(19) United States
(12) Patent Application Publication
(10) Pub. No.: US 2007/0221132 A1
(43) Pub. Date: Sep. 27, 2007

(54) Composition, coating, coated article, and method

(75) Inventors: Ramachandran Gopi Chandran, Bangalore (IN); Balasubramaniam Vaidhyanathan, Bangalore (IN); Venkat Subramaniam Venkataramani, Clifton Park, NY (US); Victor Lienkong Lou, Niskayuna, NY (US); George Theodore Dalakos, Niskayuna, NY (US); Sheela Kollali Ramasesha, Bangalore (IN)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/604,534

(22) Filed: Nov. 27, 2006

Related U.S. Application Data
(60) Provisional application No. 60/785,546, filed on Mar. 24, 2006.

(51) Int. Cl. H01L 21/306; C23C 16/00

(52) U.S. Cl. 118/728; 156/345.51; 156/914

(57) ABSTRACT

A processing apparatus for use in a corrosive operating environment at a temperature range of 25-1500° C. is provided. The apparatus has an NZP or an NZP-type coating, which comprises a first composition, a second composition, and a metal cation. The first composition and the second composition form a crystalline structure with three-dimensional network of octahedra and tetrahedra linked by one or more shared atoms. The first composition comprises one or more of Zr, V, Ta, Nb, Hf, Ti, Al, Cr, or a metal of the Lanthanide series. The second composition comprises at least one of phosphorus, silicon, boron, vanadium or aluminum. The one or more shared atoms comprise at least one of oxygen, nitrogen, or carbon. The first composition and the second composition are related as shown by the formula (first composition)₂ (second composition)ₓ (shared atom)₁₂₋ₓ. The metal cation is disposed within an interstitial site defined by the crystalline structure.

### CROSS REFERENCE TO RELATED APPLICATIONS

This patent application claims benefit and priority to U.S. Provisional Patent Application Ser. No. 60/785,546 filed on Mar. 24, 2006, the contents of which are incorporated by reference.

### TECHNICAL FIELD

The invention relates to articles and apparatuses for use in the semiconductor processing industry and other corrosive environments, and methods for making articles and apparatuses thereof. In one embodiment, the invention also relates to methods of making or using compositions for use in coating articles and apparatuses for use in the semiconductor processing industry and other corrosive environments.

### DISCUSSION OF RELATED ART

The process for fabrication of electronic devices comprises a number of process steps that rely on either the controlled deposition or growth of materials or the controlled and often selective modification of previously deposited/grown materials. Exemplary processes include Chemical Vapor Deposition (CVD), Thermal Chemical Vapor Deposition (TCVD), Plasma Enhanced Chemical Vapor Deposition (PECVD), High Density Plasma Chemical Vapor Deposition (HDP CVD), Expanding Thermal Plasma Chemical Vapor Deposition (ETP CVD), Metal Organic Chemical Vapor Deposition (MOCVD), etc. In some of the processes such as CVD, one or more gaseous reactants are used inside a reactor under low pressure and high temperature conditions to form a solid insulating or conducting layer on the surface of a semiconductor wafer, which is located on a substrate (wafer) holder placed in a reactor.

The substrate holder in the CVD process could function as a heater, which typically contains at least one heating element to heat the wafer; or could function as an electrostatic chuck (ESC), which comprises at least one electrode for electro-statically clamping the wafer; or could be a heater/ESC combination, which has electrodes for both heating and clamping. A substrate holder assembly may include a susceptor for supporting a wafer, and a plurality of heaters disposed under the susceptor to heat the wafer. The semiconductor wafer is heated within a confined environment in a processing vessel at relatively high temperature and often in an atmosphere that is highly corrosive.

After a deposition of a film of predetermined thickness on the semiconductor wafer, there often is spurious deposition on other exposed surfaces inside the reactor. This spurious deposition could present problems in subsequent depositions. It is therefore periodically removed with a cleaning process, i.e. in some cases after every wafer and in other cases after a batch of wafers has been processed. Common cleaning processes in the art include atomic fluorine based cleaning, fluorocarbon plasma cleaning, sulfur hexafluoride plasma cleaning, nitrogen trifluoride plasma cleaning, and chlorine trifluoride cleaning. In the cleaning process, the reactor components, e.g., walls, windows, the substrate holder and assembly, etc., are often corroded/chemically attacked. The corrosion can be extremely aggressive on surfaces that are heated to elevated temperatures, e.g. such as the operating temperature of a typical heater which is typically in the 400-500° C. range but can be as high as the 600-1000° C. range.

NZP and nasicon compositions have been identified as being sometimes useful as coating materials. NZP-type materials may be prepared by heating a mixture of alkali metal phosphates and tetravalent metal oxides. The various constituents of NZP compositions may include, for example, NaZr₂(PO₄)₃ and may have a crystal structure with three-dimensional network of PO₄ tetrahedra and ZrO₆ octahedra linked by shared oxygen atoms. These units may connect with each other to form ribbons along the c-axis, and that join together (perpendicular to the c-axis) by PO₄ tetrahedra to develop a three dimensional rigid network. The articulation of these ribbons and chains may create structural holes or interstitial vacant sites in the structure that are normally occupied by sodium and/or other substituting ions. There are four such interstitial sites per formula unit of which some are empty depending upon the particular substitution.

While sometimes referred as an NZP compound, derived likely from the presence of sodium (Na), zirconium (Zr), and phosphorus (P), derivatives may be prepared that substitute some or all of those constituents. For example, the sodium ions may be located at the interstitial sites created by the framework, but may be replaced with other ions to form an NZP analog. Even though the NZP structure is flexible towards ionic substitution at various lattice sites, the effect of these substitutions may not be readily predictable.

Ceramic materials with the aforementioned NZP or nasicon (Na₁₊ₓZr₂P₃₋ₓSiₓO12) structure may have an associated property, such as a relatively low thermal coefficient of expansion (CTE) and/or a good resistance to thermal shock. Others of the NZP type coatings may be resistant on one or both of acids or bases. Materials having one or more of such properties may be useful in a variety of applications.

There is still a need for articles and apparatuses suitable for semiconductor-processing environments, including those employing corrosive gases, as currently employed materials for use in articles and components such as heaters and electrostatic chucks may be lacking in one or more desired properties or characteristics. NZP type coatings and materials provide semiconductor-processing components with properties other than those currently available for coating composition and coatings in semiconductor-processing environments.

### BRIEF DESCRIPTION

The invention relates to embodiments that include a composition capable of forming an NZP or an NZP-type coating. The composition includes a first composition, a second composition, and a metal cation. The first composition and the second composition form a crystalline structure with three-dimensional network of octahedra and tetrahedra linked by one or more shared atoms. The first composition comprises one or more of Zr, V, Ta, Nb, Hf, Ti, Al, Cr, or a metal of the Lanthanide series. The second composition comprises at least one of phosphorus, silicon, boron, vanadium or aluminum. The one or more shared atoms comprise at least one of oxygen, nitrogen, or carbon. The first composition and the second composition are related as shown by the formula (first composition)₂ (second composition)ₓ (shared atom)₁₂₋ₓ. The metal cation is disposed within an interstitial site defined by the crystalline structure.

The invention relates to embodiments that include a protective system comprising a coating. The coating has a CTE matched to a corresponding substrate within about 10 percent of the substrate CTE. The coating includes substitution materials capable of resisting etching by oxidizing gas, halogen containing gas, plasma, or all of the foregoing at a temperature greater than room temperature.

The invention relates to embodiments that include a system having a heater having a surface; and a coating disposed on the surface. The coating has a crystalline structure indicated by the formula:

(L,M1,M2,Zn,Ag,Ga,In,Ln,Y,Sc)ₗ(Zr,V,Ta,Nb,Hf,Ti,Al,Cr,Ln)ₘ(P,Si,V,B,Al)ₙ(O,C,N)₁₂

wherein L=alkali, M1=alkaline earth, M2=transition metal, Ln=rare earth and the values of l,m,n are so chosen that the charge balance is maintained at a valence equivalent to that of the total non metals O,C,N.

The invention relates to embodiments that include a support structure, comprising a temperature-controllable base having a temperature less than an operating process temperature of a workpiece; an electrostatic chuck capable of supporting the workpiece, and the chuck being disposed proximate to the base and capable of receiving an incoming heat flux during an operating process; a heater in thermal communication with the electrostatic chuck; and a coating disposed on a surface of the electrostatic chuck, wherein the coating has a crystalline structure indicated by the formula:

(L,M1,M2,Zn,Ag,Ga,In,Ln,Y,Sc)ₗ(Zr,V,Ta,Nb,Hf,Ti,Al,Cr,Ln)ₘ(P,Si,B,V,Al)ₙ(O,C,N)_{w}

wherein L=alkali, M1=alkaline earth, M2=transition metal, Ln=rare earth; w=12 or 24; and the values of l,m,n are so chosen that the charge balance is maintained.

The invention relates to embodiments that include a wafer processing apparatus. The apparatus includes a platform for placement of a workpiece to be processed. The platform has a base substrate comprising at least one of graphite, a refractory metal, a transition metal, a rare earth metal, or a combination of two or more thereof; and a first protection layer disposed on a surface of the base substrate, the layer comprising at least one of an oxide, nitride, oxynitride, carbide, or nitride of one or more elements selected from a group consisting of Al, B, Si, Ga, refractory hard metals, transition metals, and combinations thereof. A film electrode may be disposed on the protection layer. A second protection layer disposed on a surface of the base substrate, the layer comprising at least one of an oxide, nitride, oxynitride, carbide, or nitride of one or more elements selected from a group consisting of Al, B, Si, Ga, refractory hard metals, and transition metals, and combinations thereof. The base substrate has a coefficient of thermal expansion (CTE) in a range of from about 0.75 to 1.25 times that of the first protection layer.

The invention relates to embodiments that include a coating comprising an NZP or NZP-type material capable of being disposed on a substrate and having an electrical resistivity in a range of from about 1=10¹⁵ to about 1=10¹⁸, and an dielectric constant of greater than about 7.

### BRIEF DESCRIPTION OF DRAWING FIGURES

FIG. 1 is a schematic cross-sectional view of an article comprising an embodiment of the invention.

### DETAILED DESCRIPTION

Approximating language, as used herein throughout the specification and claims, may be applied to modify any quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value.

As used herein, “capable of resisting etching” means being highly resistance against corrosion by corrosive gases such as fluorine and chlorine gases, and high resistance against plasma, for an etch rate in NF₃at 600° C. of less than 100 Angstroms per min (A/min). In one embodiment, “capable of resisting etching” means an etch rate in NF₃ at 600° C. of less than 50 A/min. In yet another embodiment, “capable of resisting etching” means having an etching resistance rate to 18 weight percent feedstock gas comprising oxygen gas and at least one of carbon tetrachloride gas or nitrogen fluoride gas is less than about 10 Angstroms per minute at about 600° C.

The invention may include embodiments that relate to a composition for use in a coating, relate to a coating, and relate to a coated article, i.e., heaters and/or electrostatic chucks (ESCs) for use in a semi-conductor processing environment. The invention may include embodiments that relate to methods of making or using compositions in coatings, coatings, and coated articles. Particularly, embodiments of the invention may relate to an NZP-type composition, and other embodiments may relate to substrate coating with an NZP coating. The substrate may be, for example, an article used in semiconductor wafer processing, such as a heater or an electrostatic chuck. Other articles may be used as a crucible or as a boat in metal vapor deposition.

NZP/NZP-type composition: In one embodiment, the substrate for use in a semiconductor processing environment is coated with a composition which forms an NZP or NZP-type coating when applied to a substrate. “NZP” may be used interchangeably with “NZP-type,” meaning a solid phase in which the arrangement of atoms is generally similar to that of the type compound NaZr₂P₃O₁₂, but in which some or all of the sodium, zirconium, or phosphorus is replaced by other substituent atoms. Also, additional atoms may be substituted into the crystal lattice sites that are vacant in NaZr₂P₃O₁₂, but which are fully occupied in the Na₄Zr₂Si₃O₁₂ compound, which is also an NZP-type phase. Additionally, by NZP-type, other ceramic coating layers, such as nasicon, may be identified as being suitable with reference to the end-use application of an article comprising the coating layer and the coating layer properties and/or characteristics.

The NZP composition capable of forming the coating layer may include a first composition, a second composition, and a metal cation. The metal cation may be disposed within an interstitial site defined by the crystalline structure. That is, the first composition and the second composition may form a crystalline structure, or a semi-crystalline structure, with three-dimensional network of octahedra and tetrahedra linked by one or more shared atoms. The first composition and the second composition may be related as shown by the formula:

(first composition)₂ (second composition)ₓ(shared atom)₁₂₋ₓ

The first composition may include zirconium. Suitable materials for the first composition may include one or more of V, Ta, Nb, Hf, Ti, Al, Cr, or Ln where Ln is a rare earth, Sc, or Y. Combinations of two or more of the foregoing, and particularly zirconium with one or more of the foregoing may be selected for use in the coating layer.

In one embodiment, the first composition may include one or more of alkali or alkaline materials. In another embodiment, the first composition may include one or more of Zn, Ga, In, Ag, or Ln, wherein the general composition of the coating formed from the composition is: (L,M1,M2,Zn,Ag,Ga,in,Ln,Y,Sc)ₗ (Zr,V,Ta,Nb,Hf,Ti,Al,Cr,Ln)ₘ (P,Si,VAl)ₙ(O,C,N)_{w}, wherein L=alkali, M1=alkaline earth, M2=transition metal, Ln=rare earth; w=12 or 24; and the values of l,m,n are so chosen that the charge balance is maintained.

In another embodiment, the coating composition may include two or more elements in (L,M1,M2,Zn,Ag,Ga,In,Ln,Y,Sc)ₗ (Zr,V,Ta,Nb,Hf,Ti,Al,Cr,Ln)ₘ (P,Si,V,Al)ₙ (O)_{w}, wherein L=alkali, M1=alkaline earth, M2=transition metal, Ln=rare earth; w=12 or 24; and the values of l, m, n are so chosen that the charge balance is maintained. In one embodiment, N and C substitutions are so chosen such that the charge balance is maintained. In yet another embodiment, the anionic substitution involves N for O, C for O, or both, for the replacement of PO₄ tetrahedra by other groups, e.g., (SiO, N)₄, (SiO, N, C)₄ or (Si, Al O,N) while still retaining the NZP structure.

In one embodiment with the flexible structure of the parent NZP compound, AlN tetrahedra is inserted into the structure. In a fourth embodiment, other materials can be used instead of or in addition to AlN, e.g., Sialons, YAG, Y2O3, and SiC, forming composites with the NZP compound.

In one embodiment, the zirconia-based coating may include at least one stabilizer. Suitable stabilizers may include one or both of yttria (Y₂ O₃) and calcia (CaO). Suitable other stabilizers may include one or both of alkaline earth oxides, or rare earth oxide.

The second composition may include at least one of phosphorus, silicon, boron, vanadium or aluminum. In one embodiment, the second composition consists essentially of boron. In one embodiment, the second composition consists essentially of aluminum. In one embodiment, the second composition comprises two or more of P, Si, Al, V or B. In one embodiment, the second composition comprises three or more of P, Si, Al, V or B.

The one or more shared atoms comprise at least one of oxygen, nitrogen, or carbon. In one embodiment, the shared atoms may include a plurality of C, N and O (either 2 or more with O being present in a larger amount relative to the other components (in toto). In one embodiment, the shared atoms consist essentially of nitrogen. In one embodiment, the shared atoms consist essentially of carbon. A select or determined amount of partial substitution of oxygen with carbon and/or nitrogen may produce a material with properties and characteristics suited to particular end-use applications. In one embodiment, greater than about 10 percent of the oxygen is substituted with carbon, about 10 percent to about 25 percent, about 25 percent to about 60 percent, about 60 percent to about 75 percent, about 70 percent to about 75 percent, or greater than about 75 percent of the oxygen is substituted. In one embodiment, greater than about 10 percent of the oxygen is substituted with nitrogen, about 10 percent to about 25 percent, about 25 percent to about 60 percent, about 60 percent to about 75 percent, about 70 percent to about 75 percent, or greater than about 75 percent of the oxygen is substituted. In one embodiment, greater than about 10 percent of the oxygen is substituted with carbon and with nitrogen in about equal portions, about 10 percent to about 25 percent, about 25 percent to about 60 percent, about 60 percent to about 75 percent, about 70 percent to about 75 percent, or greater than about 75 percent of the oxygen is substituted. Selection of the ratio of nitrogen to carbon in the substitution may allow for control of the characteristics and properties and tailoring for particular end-use applications.

Suitable metal cations may be selected based on the desired characteristics and properties of the coating layer with regard to the end-use application. Suitable metal cations may be a metal of Group I of the periodic table of elements. Other suitable metal cations may be a metal of Group II of the periodic table of elements. Other suitable metal cations may be a metal of the Lanthanide series. Other suitable metal cations may be a transition metal. The metal cations may be selected from two or more of the foregoing to tailor the properties and characteristics of the coating layer formed from the composition. In one embodiment, the metal cation may include two or more of Li, Na, K, Rb, Cs, Mg, Ca, Sr, Ba, Ga, In, Ag, Zn, Cr, Mn, Fe, Co, La, Lu, or Ln (Ln=Sc,Y, rare earth).

In other embodiments, permutations may be expressed that have particular characteristics and properties useful in end-use applications. Suitable permutations may include one or more of: the first composition comprises phosphorus and the one or more shared atoms comprise nitrogen; the second composition comprises silicon and the one or more shared atoms comprise nitrogen; the second composition comprises boron and the one or more shared atoms comprise nitrogen; the second composition comprises aluminum and the one or more shared atoms comprise nitrogen; the second composition comprises phosphorus and the one or more shared atoms comprise carbon; the second composition comprises silicon and the one or more shared atoms comprise carbon; the second composition comprises boron and the one or more shared atoms comprise carbon; the second composition comprises aluminum and the one or more shared atoms comprise carbon; the second composition comprises boron and the one or more shared atoms comprise oxygen; the second composition comprises aluminum and the one or more shared atoms comprise oxygen.

The ratio of the first composition to the second composition may be selected based on the desired characteristics and properties of the coating layer with regard to the end-use application. In one embodiment, the ratio of the first composition to the second composition may be about 1:1.5. In one embodiment, the ratio of the first composition to the second composition may be about 1.5:1. In one embodiment, the ratio of the first composition to the second composition may be about 1:1. In one embodiment, the ratio of the first composition to the second composition may be about 1:1.25.

In one embodiment, the NZP coating may have a formula expressed as [M][A2][B3]O₁₂ wherein M may be a metallic atom and, in one embodiment, represents interstitial sites occupied exclusively by sodium ions. In other embodiments, some interstitial sites may be occupied by sodium, and other of the interstitial sites may be occupied by other substituting ions. In another embodiment, none of the interstitial sites may be occupied by sodium, and all the interstitial sites may be occupied by other substituting ions. A and B sites may be occupied by zirconium, by phosphorus, by an ion capable of substituting for zirconium or phosphorus, or by some combination of two or more of the foregoing. The zirconium may occupy the octahedral sites, while P may occupy the tetrahedral sites and may be corner linked to form a rigid structure. The metal cations (M) may be chosen so that the charge balance is maintained such that the valence of all metals M, A and B adds up to the total valence of non-metals O, N, and C.

In one embodiment, the NZP-type coating composition is of the formula RZr₄ P₆ O₂₄ wherein R is one or more cations of group IIa in the periodic table, such as Ba, Sr and Ca. In one embodiment, R is Ba. In a second embodiment, R is Ca. In one embodiment, the coating composition has an average thermal expansion coefficient between room temperature and 1,400° C. of −10 to +10×10⁻⁷/° C. and a high temperature crystalline structure having R3c symmetry at room temperature.

In one embodiment, the NZP-type composition has the formula (Ca₁₋ₓ, Mgₓ)Zr₄ (PO₄)₆ where x ranges between 0.1 and 0.9. In one example, x is 0.4.

In one embodiment, the NZP-type composition has the formula R_{1-Y}⁴⁺ R_{Y}¹⁺ R_{Y}³⁺ V_{2-X} P_{X} O₇ , wherein X is from about 0.1 to about 1.9, Y is from about 0.0 to about 0.4, and wherein R⁴⁺ selected from the group consisting of Hf, Zr, Zrₐ M_{b}, Hfₐ M_{b} and mixtures thereof, wherein a+b=1, and M is selected from the group consisting of Ti, Ce, Th, U, Mo, Pt, Pb, Sn, Ge and Si, R¹⁺is selected from alkali earth metals, and R³⁺is selected from the group of rare earth metals, Y or Sc.

In one embodiment, the NZP-type composition has the formula R_{1+X}M₄ P_{6-2X} Si_{2X} O₂₄ wherein X is a number having a value of between about 0.2 and 0.8, R is one or more cations of group IIa in the periodic table, such as strontium, barium or mixtures thereof, and M is selected from the group consisting of Hf, Zr, Zrₐ M_{b}, Hfₐ M_{b} and mixtures thereof.

In one embodiment, the NZP-type composition is of the formula A₂₋ₓ³⁺ A_{y}⁴⁺ M_{z}³⁺ M_{3-y}⁶⁺ P_{y}O₁₂ where A³⁺is a metal having an oxidation state of +3, A⁴⁺ is a metal having an oxidation state of +4, M³⁺ is a metal having an oxidation state of +3, M⁶⁺ is a metal having an oxidation state of +6, y varies from about 0 to about 2, x=y+z, and x varies from about 0.1 to about 1.9.

In one embodiment, the NZP-type composition is of the formula the general formula Rₓ Z₄ P_{6-y}Si_{y}O₂₄, wherein 0<=x<=8, 0<=y<=6, R is selected from the group consisting of Li, Na, K, Rb, Cs, Mg, Ca, Sr, Ba, Y, lanthanides, and combinations thereof, Z is selected from the group consisting of Zr, Ti, Nb, Ta, Y, Sc, lanthanides, and combinations thereof.

A plurality of particles may be dispersed within the NZP or NZP-type coating layer. The particles may be included during the formation of the coating layer. Suitable particles may include, for example, aluminum nitride or silicon carbide. The particles may have an average particle size that less than about 100 micrometers. In one embodiment, the particles may have an average particle size in a range of from about 100 micrometers to about 75 micrometers, from about 75 micrometers to about 50 micrometers, about 50 micrometers, from about 50 micrometers to about 25 micrometers, from about 25 micrometers to about 15 micrometers, from about 15 micrometers to about 10 micrometers, or from about 10 micrometers to about 5 micrometers. Alone, or in combination with micrometer-sized particles disclosed above, nano-scale particle may be included in the coating layer. The nano-scale, or sub-micron sized, particles may be present in an amount that packs into voids formed between micrometer-sized particles. If nano-scale particles are present, the particles may have an average particle size in a range of from about 1000 nanometers to about 750 nanometers, from about 750 nanometers to about 500 nanometers, from about 500 nanometers to about 250 nanometers, from about 250 nanometers to about 100 nanometers, from about 100 nanometers to about 75 nanometers, from about 75 nanometers to about 50 nanometers, or less than about 50 nanometers. While the nano-scale particles and the micro-scale particles may be of the same material, in one embodiment, the nano-scale particles and the micro-scale particles may be formed of differing materials relative to each other.

The metal cation, disclosed above, may be present in the coating layer an amount sufficient that the interstitial sites empty, or are free of the metal cation. The interstitial sites may then be occupied at a later time though, for example, a diffusion mechanism. In another embodiment, the interstitial sites may be fully occupied, or may be partially occupied. For an NZP coating layer, if the interstitial sites are partially occupied, the interstitial sites may be 50 percent occupied if a divalent metal cation is present, or may be 33 percent occupied if a trivalent cation is present. In one embodiment, the metal cation may be present in an amount sufficient that the interstitial sites are off a stoichiometric balance of 1:1.

Selection of particulate inclusions, disclosed hereinabove, based on one or more of size, morphology, composition, method of inclusion, characteristics, or properties may allow control over macroscopic functionality of the coating layer. For example, inclusion of aluminum oxide nano-scale particulates may increase the wear resistance, the abrasion resistance, the thermal transfer ability, and other properties of the coating layer in a manner attributable to the concentration by weight percent of the particles in the coating layer.

In one embodiment, zirconia and related stabilized zirconia compositions, as well as other oxide and non-oxide ceramic compositions, may be sintered or coated as a layer onto a substrate surface. Suitable oxides may include one or more of hafnia, alumina, beta-alumina, silica, titania, mullite, spinet, chromium oxide, zircon, sialon, or nasicon. Suitable non-oxides may include one or more of aluminum carbide, boron carbide, silicon carbide, titanium carbide, zirconium carbide, aluminum nitride, boron nitride, silicon nitride, titanium nitride, zirconium nitride, or titanium diboride. Suitable oxynitrides may include one or more of aluminium oxynitride, sialons, alkaline earth aluminium silicon oxynitride, or rare earth aluminium silicon oxynitride.

The fabrication of a thin outer coating layer may be achieved by drawing one or more continuous length of green sheet through a sintering furnace, and applying the green sheet to the substrate surface. A suitable sheet sintering method may include firing discrete green sheet while the sheet contacts the substrate surface. Coating defects analogous to sheet curling or sheet texturing may be reduced or eliminated by controlling the amount, timing and/or duration of non-uniform static or dynamic frictional forces arising between the sheet and the substrate surface during formation. In one embodiment, a press may apply pressure to the sheet to reduce movement.

The green sheet may be pre-sintered. Pre-sintering the sheet may provide control over the phase assemblage and grain size of the polycrystalline ceramic coating layer. Crystal grain size in the final coating may affect the oxygen ion conductivity of zirconia-based electrolyte materials.

The green sheet may be reshaped, for example, by plastic or superplastic deformation, at or near the sintering temperatures of the ceramic, to provide a determined shape. Such determined shapes may include corrugated or other curved layers.

The heat bonding characteristics of a pre-sintered green sheet may allow multiple sheets or sheet stacks to permanently bond to themselves and to other ceramic, cermet and metallic material surfaces. A suitable bond may be formed without the use of supplemental sealing materials. In one embodiment, a suitable bond may be formed by low pressure lamination at or near a sintering temperature of the green sheet material. A gas-tight seal between mating surfaces may be provided.

In addition to forming the coating by contacting a green sheet to the substrate surface and heat bonding thereto, other application methods suitable to form the coating layer may be used. Such suitable methods may include one or more of plasma spraying, sol-gel forming, hot isostatic pressing, and the like.

Properties of Heaters/Chucks Having NZP Coatings: In one embodiment, the coating layer may be an NZP or NZP-type material that can be coated or deposited onto a surface of the heater/ESC substrate, and may have one or more controllable property or characteristic. The property or characteristic may be affected by the selection of coating layer composition materials. In one embodiment, the electrical resistivity may be affected by selection of dopant(s) and the selection of the doping amounts. The coating layer may have an electrical resistivity of greater than about 10¹² Ohm meter. In one embodiment, the electrical resistivity may be in a range of from about 10¹² Ohm meter to about 10¹³ Ohm meter, from about 10¹³ Ohm meter to about 10¹⁴ Ohm meter, from about 10¹⁴ Ohm meter to about 10¹⁵ Ohm meter, from about 10¹⁵ Ohm meter to about 10¹⁶ Ohm meter, from about 10¹⁶ Ohm meter to about 10¹⁷ Ohm meter, from about 10¹⁷ Ohm meter to about 10¹⁸ Ohm meter, or greater than about 10¹⁸ Ohm meter. By selection of the substituting ion and/or dopants, the coating layer may be affected to be semi-conductive or even conductive. For example, the coating layer may have an electrical resistivity of less than about 10¹² Ohm meter. In one embodiment, the electrical resistivity may be in a range of from about 10¹² Ohm meter to about 10¹⁰ Ohm meter, from about 10¹⁰ Ohm meter to about 10⁸ Ohm meter, from about 10⁸ Ohm meter to about 10⁶ Ohm meter, from about 10⁶ Ohm meter to about 10⁴ Ohm meter, from about 10⁴ Ohm meter to about 10² Ohm meter, or less than about 100 Ohm meter. Electrical resistivity is a measure indicating how strongly a material opposes the flow of electric current. The electrical resistivity values may be unit measures at process conditions to account for temperature dependence.

Dielectric constant or permittivity is a measure of the ability of the coating to resist the formation of an electric field within the coating layer. By selecting the composition for forming the coating layer, the dielectric constant of the coating layer may be affected. The coating layer may have a dielectric constant in a range of greater than about 5. In one embodiment, the coating layer may have a dielectric constant in a range from about 5 to about 6, from about 6 to about 7, from about 7 to about 8, or greater than about 8. The dielectric constant may be measured with reference to frequency. Depending on the composition selection the frequency may be greater than about 1000 kiloHertz. In one embodiment, the frequency may be in a range of from about 1000 kiloHertz to about 10 megaHertz, from about 10 megaHertz to about 100 megaHertz, from about 100 megaHertz to about 1 gigaHertz, from about 1 gigaHertz to about 2 gigaHertz, from about 2 gigaHertz to about 3 gigaHertz, or greater than about 3 gigaHertz.

By controlling the composition selection of the coating layer and/or the deposition or coating method, and/or firing time and temperature the porosity of the coating may be affected. The porosity of the coating layer may be less than 15 volume percent. In one embodiment, the coating layer porosity may be in a range of from about 15 volume percent to about 10 volume percent, from about 10 volume percent to about 5 volume percent, from about 5 volume percent to about 2.5 volume percent, or less than about 2 volume percent. The pores, if present, may be non-connecting so that even if voids or pores are present, the surface integrity or continuity of the coating layer is not breached or compromised.

By controlling the composition selection of the coating layer and/or the deposition or coating method, and/or firing time and temperature the thermal diffusivity of the coating may be affected. The thermal diffusivity of the coating layer may be in a range of greater than about 6×10⁻⁷ m²/sec. In one embodiment, the thermal diffusivity of the coating layer may be in a range of from about 6×10⁻⁷ m²/sec to about 1×10⁻⁶ m²/sec, from about 1×10⁻⁶ m²/sec to about 1×10⁻⁵ m²/sec, from about 1×10⁻⁵ m²/sec to about 1×10⁻⁴ m²/sec, from about 1×10⁻⁴ m²/sec to about 1×10⁻³ m²/sec, or greater than about 1×10⁻³ m²/sec.

By controlling the composition selection of the coating layer and/or the deposition or coating method, and/or firing time and temperature the thermal conductivity of the coating may be affected. The thermal conductivity of the coating layer may be in a range of from about 0.01 W/m-K to about 0.1 W/m-K, from about 0.1 W/m-K to about 1 W/m-K, from about 1 W/m-K to about 1.1 W/m-K, or greater than about 1.1 W/m-K.

By controlling the composition selection of the coating layer and/or the deposition or coating method, and/or firing time and temperature the coefficient of thermal expansion (CTE) of the coating may be affected. The coefficient of thermal expansion may be greater than about 0.1. In one embodiment, the coefficient of thermal expansion may be in a range of from about 0.1 to about 0.5, from about 0.5 to about 1, from about 1 to about 1.5, from about 1.5 to about 2, from about 2 to about 2.2, from about 2.2 to about 2.3, about 2.3, from about 2.3 to about 2.4, from about 2.4 to about 2.5, or greater than about 2.5. By another measure, the coating layer may have a coefficient of thermal expansion matched to the substrate, or to the undercoating layer on a coated substrate, by a determined percent difference. The determined percent difference may be less than about 10 percent. In one embodiment, the determined percent difference may be in a range of from about 10 percent to about 5 percent, from about 5 percent to about 2.5 percent, from about 2.5 percent to about 1 percent, from about 1 percent to about 0.5 percent, or less than about 0.5 percent difference in the coefficient of thermal expansion from coating layer to the substrate.

In one embodiment, the NZP coating layer may resist damaging effects in harsh environments. Particularly, the layer may resist etching when contacted to a halogen at a temperature in a range of greater than about 100 degrees Celsius. Halogens may include one or more of fluorine, chlorine, or bromine. In one embodiment, the environment may include an oxidant, such as oxygen. In one embodiment, the environment may include a solvent, such as carbon tetrachloride. The temperature may be in a range of from about 100 degrees Celsius to about 250 degrees Celsius, from about 250 degrees Celsius to about 500 degrees Celsius, from about 500 degrees Celsius to about 600 degrees Celsius, from about 600 degrees Celsius to about 700 degrees Celsius, from about 700 degrees Celsius to about 800 degrees Celsius, from about 800 degrees Celsius to about 900 degrees Celsius, from about 900 degrees Celsius to about 950 degrees Celsius, from about 950 degrees Celsius to about 1000 degrees Celsius, or greater than about 1000 degrees Celsius. The harsh environment may be acidic and may have an effective pH of less than about 6, in a range of from about 6 to about 4, from about 4 to about 2, or less than about 2. The environment may include plasma that may contain energized ions. Plasma environments may be relatively more likely to etch than other harsh environments, such as those environments containing halogens and oxidants at high temperatures. In the harsh environment, the etch resistance of the coating layer may be sufficient that the material loss of the coating layer is less than about 100 Angstroms per minute at a temperature of greater than about 400 degrees Celsius in the presence of a halogen and an oxidant. In one embodiment, the material loss rate may be less than about 50 Angstroms per minute, less than about 35 Angstroms per minute, or less than about 10 Angstroms per minute at about 400 degrees Celsius.

In the harsh environment, the coating layer may resist delamination, pitting, and cracking. Particularly, the coating layer may resist cracking due to thermal cycling of the substrate and/or thermal shock.

Heaters and Chucks Having NZP Coatings: As disclosed hereinabove, a heater/ESC comprising an embodiment of the invention may include the NZP/NZP-type coating layer disposed on a substrate. Suitable substrates for use with the coating layer may include one or more of fused silica or quartz (CTE=0.5), graphite, boron nitride, silicon carbide, and pyrolitic derivatives thereof. In one embodiment, the substrate comprises one of graphite; refractory metals, transition metals, rare earth metals and alloys thereof; a sintered material including at least one of oxide, nitride, carbide, carbonitride or oxynitride of elements selected from a group consisting of B, Al, Si, Ga, Y, refractory hard metals, transition metals; oxide, oxynitride of aluminum; and combinations thereof. In yet another embodiment, the base substrate comprises high thermal stability zirconium phosphate having an NZP structure of NaZr₂ (PO₄)₃; refractory hard metals; transition metals; oxide, oxynitride of aluminum, and combinations thereof.

Pyrolitic graphite is a crystalline carbonaceous structure in which there is a relatively high degree of crystallite orientation relative to what may be found in common graphite materials. The pyrolitic graphite may exhibit anisotropic physical properties, and may be characterized by oriented slip planes.

The anisotropic properties may be measurable different in contrast to isotropic properties of common graphite. Pyrolitic graphite may be formed by chemical vapor decomposition of, for example, methane gas at relatively high temperature in a reactor chamber with a suitable inert diluent. The pyrolitic graphite may have a thermal conductivity in an orientable direction in a range, in plane, of about 500 watt/meter-K or greater. In one embodiment, the in-plane thermal conductivity may be in a range of from about 500 watt/meter-K to about 600 watt/meter-K, from about 600 watt/meter-K to about 700 watt/meter-K, or greater than about 700 watt/meter-K. Skew relative to the plane, and the thermal conductivity may be less than about, 10 watt/meter-K. In one embodiment, the out of plane thermal conductivity may be in a range of from about 10 watt/meter-K to about 7.5 watt/meter-K, from about 7.5 watt/meter-K to about 5 watt/meter-K, from about 5 watt/meter-K to about 3.5 watt/meter-K, or less than about 3.5 watt/meter-K.

Regardless of the substrate, by incorporated one or more determined dopants or one or more substituted ions, the emissivity of the coating layer may be controlled. The emissivity of commercially available pyrolitic boron nitride heating units may be about 0.55 at a wavelength of 1.55 micrometers wavelength. For purposes of comparison an ideal black body at the same wavelength would have a radiation thermal efficiency of 100% representing a measurement of 1.00. In one embodiment, the pyrolitic boron nitride coating may have an emissivity greater than about 0.55, in a range of from about 0.55 to about 0.65, from about 0.65 to about 0.7, from about 0.7 to about 0.75, from about 0.75 to about 0.8, from about 0.8 to about 0.85, or greater than about 0.85.

In particular, a pyrolitic boron nitride surface may support a coating layer having a coefficient of thermal expansion that is matched to a determined amount to the pyrolitic boron nitride. Determined amount of coefficient of thermal expansion match may be expressed as a percentage difference or as a ratio of coefficients of thermal expansion. With regard to percent difference, in this instance, the determined amount may be less than about 10 percent, in a range of from about 10 percent to about 5 percent, from about 5 percent to about 2 percent, from about 2 percent to about 1 percent, or less than 1 percent difference. With regard to ratio, the pyrolitic boron nitride may have a coefficient of thermal expansion of about 2.3, and the coating may have a coefficient of thermal expansion in a range of from about 2 to about 2.2, from about 2.2 to about 2.3, 2.3, or from about 2.3 to about 2.4; so that the ratio may be about 1:1.

The thickness of the pyrolitic graphite, if an undercoating, may provide a determined amount of spatial separation between a graphite body and a pyrolitic boron nitride layer and may provide a controllable amount of thermal leveling. Prior to application of the NZP coating layer according to an embodiment of the invention, the substrate may be pre-coated. The pre-coated substrate may be referred to herein as the substrate or as the coated substrate and care should be taken that the coated substrate that is ready for coating with the coating layer is not confused with the finished article, which will have a coating layer disposed on the substrate surface, or on the surface of the pre-coat layer on the substrate. Particularly, the substrate may be a coated substrate, or may be a multi-layered article.

In one embodiment, the substrate is first coated with the NZP coating layer, then overcoated with another layer, e.g., a coating layer comprising at least one of an oxide, nitride, oxynitride, carbide, or nitride of one or more elements selected from a group consisting of Al, B, Si, Ga, Y, refractory hard metals, transition metals, and combinations thereof. In another embodiment, the NZP coating layer is applied after the substrate is first coated with undercoating layers.

A number of materials may be useful as substrate undercoating coating layers. Such materials may include metal carbide. Suitable metal carbides may include one or more of boron carbide, tantalum carbide, or silicon carbide. If present, the coating layer of the graphite body may include one or more of a nitride, carbide, carbonitride or oxynitride of elements B, Al, Si, Ga, as well as refractory hard metals, transition metals, and rare earth metals. Other suitable coating materials may include complexes and/or combinations of two or more thereof.

In one embodiment, the undercoating layer may include one or more of pyrolitic boron nitride, aluminum nitride (AIN), a complex of AIN and BN, pyrolitic boron nitride (PBN) and a carbon dopant, aluminum nitride including an amount of Y₂O₃. Because some of the substrate undercoating layers may be colored differently relative to the substrates, the coating layer integrity may be visually determinable.

Embodiments of heaters and ESCs may include multi-layer coating layers and/or gradient or graded concentration coating layers. For example, on a pyrolitic boron nitride substrate using a sodium zirconium phosphate coating layer the coating layer may a sub-layer adjacent to the pyrolitic boron nitride surface that may be about 90 wt. % pyrolitic boron nitride and about 10 wt. % of the sodium zirconium phosphate, while an outward-facing sub-layer may be less than 5 wt. % pyrolitic boron nitride and greater than 95 wt. % of the sodium zirconium phosphate. The concentration gradient may vary in a linear or a non-linear proportion across the thickness of the coating layer. Such a graded concentration may be obtained by introducing select ingredients into the reaction/deposition chamber during the formation of the coating layer for co-deposition.

Suitable methods for depositing a coating layer or layers onto the substrate may include physical vapor deposition (PVC), wherein the coating material, e.g. boron nitride and/or aluminum nitride transfers, in vacuum, into the gaseous phase through a purely physical method to deposit on the substrate surface. Sputtering can be used, wherein a solid target may be bombarded by atomized high-energy ion particles in vacuum or an inert gas environment. Another deposition method may include chemical vapor deposition (CVD). In contrast to the PVD method, the CVD method has one or more associated chemical reactions. The gaseous components produced at relatively elevated temperatures through thermal, plasma, photon or laser-activated chemical vapor deposition may transfer with an inert carrier gas, e.g. argon into a reaction chamber in which the chemical reaction takes place.

Pyrolitic boron nitride (PBN) may be formed by chemical vapor deposition of boron nitride in a reactor chamber by the vapor phase reaction of ammonia and a boron containing gas such as boron trichloride (BCl₃). The pyrolitic boron nitride may be relatively pure. In one embodiment, the pyrolitic boron nitride may be doped with a thermally conductive material, an electrically conductive material, or a material that is both thermally conductive and electrically conductive. A suitable conductive material may be carbon. The carbon, as a dopant, may be present in an amount in an amount of less than about 5 weight percent of pyrolitic boron nitride composition. In one embodiment, the carbon may be present in an amount in a range of from about 5 weight percent to about 4 weight percent, from about 4 weight percent to about 3 weight percent, from about 3 weight percent to about 2 weight percent, from about 2 weight percent to about 1 weight percent, from about 1 weight percent to about 0.5 weight percent, or less than about 0.5 weight percent. The doped pyrolitic boron nitride coating may be formed by the codeposition of pyrolitic boron nitride and pyrolitic graphite (PG). The codeposition may be performed by introducing a hydrocarbon gas such as, for example, methane into the reactor furnace during the deposition of pyrolytic boron nitride. Codepositing pyrolitic boron nitride with pyrolitic graphite (PG) may deposit the components at about the same rate as each other, but the carbon codeposition may be less, by a factor of about greater than or equal to 20, relative to a pure deposit because ammonia may remove deposited carbon as HCN.

A pyrolitic boron nitride heating unit may include a dielectric base of boron nitride and a heating element formed from a conductive material capable of resistive heating such as graphite (collectively “heater”). The graphite may include pyrolitic graphite. The heating element may connect to an external power supply or may be capable or susceptible to heating as a response to radiation energy input.

In one embodiment, a free standing pyrolitic boron nitride structure may be formed by the thermal decomposition of boron trichloride and ammonia vapors at a reaction temperature in a range of from about 1450 degrees Celsius and 2300 degrees Celsius. The pyrolitic boron nitride substrate may be codeposited with silicon to achieve a low thermal expansion in close conformity to the thermal expansion of carbon or graphite material under controlled conditions of gas flow rate and deposition temperature. The codeposited coating may include a complex of PB(Si)N containing essentially no free silicon. To increase the silicon content in the coating composition to be in a range of from about 7 weight percent to about 35 weight percent, the deposition temperature may be controlled to be in a temperature range of from about 1300 degrees Celsius to about 1500 degrees Celsius, and the ammonia flow rate may be relative higher than the flow rate of boron and silicon.

In one embodiment, a suitable substrate, or undercoated substrate, may include silicon reacted with boron and nitride in a compositional relationship expressed as BSiₓ N₁+1.33x, with essentially no free silicon present. The content of silicon may be in a range of from about 2.0 weight percent Si to about 42 weight percent Si. With a silicon content of the substrate, or an undercoat on the substrate, of about 7.0 weight percent, the rate of oxidative weight loss of the coating, by itself, at about 1500 degrees Celsius is one-tenth that of a pure pyrolitic boron nitride substrate. Silicon content of above 35.0 weight percent may be undesirably brittle.

In one embodiment, the substrate may be a low-expansion, high-modulus carbon-carbon composite. The carbon-carbon composite may be a woven mat or fabric of carbon fibers with a carbonaceous material directly bonded to the carbon fibers to form a unitary structure. Other suitable carbon-carbon composites may include a non-woven fabric infused with a carbonaceous material bonded to the carbon fibers. An example of a carbon-carbon composite is a woven fabric of carbon fibers obtained by carbonizing polyacrylonitrile (PAN) fibers, forming a shaped substrate from the carbon fibers, and depositing a pyrolitic material such as pyrolitic carbon on the carbon fibers. The deposition of pyrolitic carbon may include introducing a hydrocarbon gas into the furnace containing the carbon fiber substrate under conditions permitting the gas to decompose and carbonize at the surface of the carbon fibers.

Carbon-carbon or graphite substrates can be mounted within the deposition chamber. For example, thin strips can be supported in V-shaped slots; plates can be supported on rods or slats; and the substrates may be suspended from screws or supported on the ends of sharpened rods.

In the growth of superconducting films, it may be sometimes useful to introduce oxygen into the atmosphere of the reacting chamber in which the superconducting film is grown. The oxygen in that atmosphere may react with the graphite conductor in the heating unit to oxidize the conductor causing an open circuit unless a precaution is taken. Because existing electrical contacts for pyrolitic boron nitride heating units may include a screw or clamp to for bias against the pyrolitic graphite conductor, the screw or clamp element may be exposed to the reactive atmosphere. This type of contact arrangement is not impermeable to a reactive gas and if the temperature at the point of contact with the graphite heating element may be sufficiently high (such as about 400 degrees Celsius) that oxidation occur without the precaution. Thermal stress may cause the screw or clamp to lose pressure at the point of contact. Loss of pressure may allow a gap and may cause arcing at the contact terminal. Arcing may damage the heating unit.

Applications for Substrates coated with NZP Coatings: Suitable end-use applications may include one or more articles used for semiconductor wafer processing in plasma environment. Such articles may include one or more of a heater, a chuck, a combined heater/chuck, and a susceptor. Other suitable end-use applications may include an article used for semiconductor wafer processing, flat panel display processing, photovoltaic device processing, and other flat panel electronic device processing applications.

Heaters with substrate coated with NZP coatings may also be useful in processing involving molecular beam epitaxy, low-gravity experimentation, electron microscopy, and in the growth of superconducting films. The substrate for NZP coating may also be a boat. Suitable boats may be useful for vacuum metal vapor deposition onto receiving substrates of metal, glass, or plastic. Suitable metals for deposition may include one or more of aluminum, copper, tin, or zinc. Resistance heated vaporization boats may include one or more intermetallic composite materials. Suitable intermetallic composite materials may include one or more of titanium diboride and boron nitride; titanium diboride and aluminum nitride; boron nitride and aluminum nitride; or titanium diboride, boron nitride and aluminum nitride. The vaporization boat may include a layer of pyrolytic boron nitride overcoated by the composite material. Fabrication of a suitable boat may include producing a rectangular substrate of graphite, which is then coated with the pyrolytic boron nitride. The opposite ends of the substrate may remain exposed to permit the boat to be electrically connected in circuit with a power supply via a contact assembly or clamp.

In one embodiment, the article is used as an electrostatic chuck for use in wafer processing. An electrostatic chuck may be a clamping device. The chuck may hold a semiconductor wafer in a clamped, fixed position during semiconductor wafer manufacture. A clamping force may be created by generating an electrostatic field around the chuck. The field may impart an electrical charge upon a conductor proximate to the wafer. A dielectric material may separate the conductor from the wafer, with the wafer disposed between a power source and the conductor in a monopolar configuration in which the wafer serves also as an electrode. Alternatively, the configuration may be a dipolar configuration. In either configuration, the insulating dielectric layer may separate the charged electrode(s). To reduce or eliminate the tendency to crack between, for example, the conductor and the insulator the thermal expansion coefficient differential may be reduced or eliminated. The electrostatic attraction force or “chuck clamping force” may be increased by limiting the resistivity of the insulator to a value smaller than 10¹⁴ Ohms-cm. Stated otherwise, a large supplementary clamping force may be generated if a current of very low magnitude is permitted to pass through the insulative separator. This is known as the “Johnsen-Rahbek” effect. The electrical resistivity of the coating, functioning as an insulating layer, may be of a value smaller than 10¹⁴ Ohms-cm. In one embodiment, the resistivity may be in a range of from about 10¹⁴ Ohms-cm to about 10¹³ Ohms-cm, from about 10¹³ Ohms-cm to about 10¹² Ohms-cm, from about 10¹² Ohms-cm to about 10¹¹ Ohms-cm, from about 10¹¹ Ohms-cm to about 10¹¹ Ohms-cm, from about 10¹⁰ Ohms-cm to about 10⁹ Ohms-cm, from about 10⁹ Ohms-cm to about 10⁸ Ohms-cm, or less than about 10⁸ Ohms-cm. The charge dissipation time for the wafer may be less than about 2 seconds, in a range of from about 2 seconds to about 1 second, from about 1 second to about 0.5 seconds, or may be less than about 0.5 seconds.

With regard to the structure of an article comprising an embodiment of the invention, a plurality of configurations may be selected based on the end-use application. In one embodiment, the article may be arranged to have a graphite/pyrolitic boron nitride basecoat/pyrolitic graphic electrode/pyrolitic boron nitride overcoat/NZP etch resistant layer. In another embodiment, the configuration may be graphite/pyrolitic boron nitride basecoat/pyrolitic graphic electrode/NZP etch resistant overcoat layer. In another embodiment, the configuration may be pyrolitic boron nitride substrate/pyrolitic graphic electrode/pyrolitic boron nitride overcoat/NZP etch resistant layer. In yet another embodiment, the configuration may be pyrolitic boron nitride substrate/pyrolitic graphic electrode/NZP etch resistant overcoat layer. In another embodiment, the configuration may be a hot pressed boron nitride substrate/pyrolitic graphic electrode/pyrolitic boron nitride overcoat/NZP etch resistant layer. In yet another embodiment, the configuration may be a hot pressed boron nitride substrate/pyrolitic graphic electrode/NZP etch resistant overcoat layer. In another embodiment, the configuration may be another insulating substrate/pyrolitic graphic electrode/PBN pyrolitic graphic overcoat/NZP etch resistant layer; or the configuration may be another insulating substrate/PG electrode/NZP Etch resistant overcoat layer; where “another insulating substrate” may include one or more oxides, nitrides, oxynitride, carbides, and mixtures of two or more thereof.

In a particular embodiment, the configuration may include a conductive or an insulating substrate with at least one undercoating layer, and which may include at least one electrode layer overcoated with an NZP etch resistant material. In another embodiment, a bulk NZP heater with embedded electrodes inside may be formed.

For substrates distinct from the end-use application, a coating layer according to an embodiment of the invention could be used with a substrate comprising one or more of Si, GaAs, AlN, GaN, glass, or another substrate.

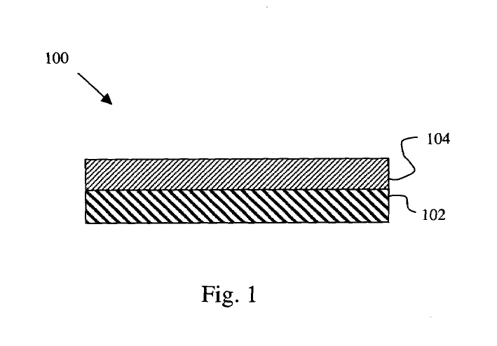

An article 100 comprising an embodiment of the invention is shown in FIG. 1. The article 100 includes a substrate 102 and a coating layer 104 disposed on an outward facing surface of the substrate 102. In the illustrated embodiment, the substrate is a pyrolitic boron nitride heater for use in a wafer processing device. The coating is an NZP coating that is commercially available from Smaht Ceramics, Inc. (Salt Lake City, Utah).

### EXAMPLES

The following illustrate methods and embodiments in accordance with the invention, and as such should not be construed as imposing limitations upon the claims. Unless specified otherwise, all ingredients are commercially available from such common chemical suppliers as Alpha Aesar, Inc. (Ward Hill, Mass.), Spectrum Chemical Mfg. Corp. (Gardena, Calif.), and the like.

### Comparative Example 1

A metal cation solution having 1 molar concentration of Na is prepared by dissolving sodium nitrate in 3 liters of water. A zirconium cation solution having 2 molar concentration of Zr is prepared by dissolving zirconium oxychloride in 2 liters of water and the two solutions are mixed thoroughly to obtain a homogeneous mixture. Phosphoric acid is dissolved in 2 liters of water to obtain 3 molar concentration of phosphorous in the solution. The solution is added to the homogeneous mixture of metal cation solution and zirconium cation solution drop wise while stirring to obtain a gel. The gel thus obtained is dried initially at 110 degrees Celsius for 2 hours and then at 150 degrees Celsius for the next 2 hours to remove moisture and then sintered at a temperature of 900 degrees Celsius in a kiln for 10 hours. Metal zirconium phosphate with about 1:2:3 molar concentration of NZP is obtained.

### Example 1

Coating pyrolitic boron nitride using sol-gel method. In a flask, water-soluble precursors are combined to precipitate a gel. The gel is recovered dried, calcined, pressed into pellets, and fired at 850 degrees Celsius. The resulting ceramic product is ground or milled, and the particles are porous. The pores range in size from about 25 nanometers (nm) to about 50 nm based on the milling technique used. The particles have a surface area of greater than about 50 m²/g.

The particle formation is repeated with differing additives. Hydroxyapatite, which has a needle-like morphology, is mechanically mixed with the calcined gel to template NZP crystallization. The reaction product had a relative coarsening of the pore structure and a decrease in surface area.

Copper nitrate is added to a solution during synthesis, the resulting ceramic shrinks upon firing, and increases in strength. Hydroxyapatite and copper additions combined result in about 40 percent volume shrinkage and a doubling of the tensile strength to about 16 MPa.

A differing porosity is achieved when silica is partly substituted for phosphorous in the NZP structure, which is known as Nasicon.

### Example 2

The procedure detailed above is repeated with Na(₃)Zr(₂)(Si(₂)P)O(₁₂)(NASICON, Na₁₊ₓZr₂SiₓP₃₋ₓO₁₂) rather than NZP. The fired ceramic has a reticulated pore structure comprising large cavities range in size from about 5 micrometers to about 50 micrometers. The NASICON ceramic shrinks or expands upon firing depending on when the silica was added during synthesis. Thus, silica additions control shrinkage in a determinable manner. Adding the silica precursor (amorphous, precipitated silica) before the calcining step causes the pressed pellets to expand during firing. Adding the silica after the gel is calcined results in shrinkage. The observed dilation increased with increasing calcining temperature and particle size, up to about 26 percent. The contraction of the ceramic when fired increases with increasing calcining temperature and a greater surface area of the gel.

Silica fiber addition, rather than particles, combined with controlled densification results in a relative improvement in strength.

Reference is made to substances, components, or ingredients in existence at the time just before first contacted, formed in situ, blended, or mixed with one or more other substances, components, or ingredients in accordance with the present disclosure. A substance, component or ingredient identified as a reaction product, resulting mixture, or the like may gain an identity, property, or character through a chemical reaction or transformation during the course of contacting, in situ formation, blending, or mixing operation if conducted in accordance with this disclosure with the application of common sense and the ordinary skill of one in the relevant art (e.g., chemist). The transformation of chemical reactants or starting materials to chemical products or final materials is a continually evolving process, independent of the speed at which it occurs. Accordingly, as such a transformative process is in progress there may be a mix of starting and final materials, as well as intermediate species that may be, depending on their kinetic lifetime, easy or difficult to detect with current analytical techniques known to those of ordinary skill in the art.

Reactants and components referred to by chemical name or formula in the specification or claims hereof, whether referred to in the singular or plural, may be identified as they exist prior to coming into contact with another substance referred to by chemical name or chemical type (e.g., another reactant or a solvent). Preliminary and/or transitional chemical changes, transformations, or reactions, if any, that take place in the resulting mixture, solution, or reaction medium may be identified as intermediate species, master batches, and the like, and may have utility distinct from the utility of the reaction product or final material. Other subsequent changes, transformations, or reactions may result from bringing the specified reactants and/or components together under the conditions called for pursuant to this disclosure. In these other subsequent changes, transformations, or reactions the reactants, ingredients, or the components to be brought together may identify or indicate the reaction product or final material.

Throughout the specification and appended claims, range limitations may be combined and/or interchanged. Such ranges are identified and include all the logical sub-ranges contained therein unless context or language indicates otherwise. The embodiments described herein are examples of compositions, structures, systems, and methods having elements corresponding to the elements of the invention recited in the claims. This written description may enable those of ordinary skill in the art to make and use embodiments having alternative elements that likewise correspond to the elements of the invention recited in the claims.

1. A processing apparatus for use in a semiconductor processing chamber, the apparatus comprising:
a base substrate for placing a wafer thereon, the base substrate has a coefficient of thermal expansion (CTE),
at least one electrode embedded in or disposed on or under the base substrate, selected from a resistive heating electrode, a plasma-generating electrode, an electrostatic chuck electrode, and an electron-beam electrode, the electrode has a coefficient of thermal expansion (CTE) in a range of 0.75 to 1.25 times that of the base substrate CTE;
at least a coating layer disposed on the base substrate, the coating layer comprising a composition capable of forming an NZP-type coating which comprises:
a first composition and a second composition, wherein the first composition and the second composition are capable of forming a crystalline structure with three-dimensional network of octahedra and tetrahedra linked by one or more shared atoms, wherein
the first composition comprises one or more of Zr, V, Ta, Nb, Hf, Ti, Al, Cr, or a metal of the Lanthanide series,
the second composition comprises at least one of phosphorus, silicon, boron, vanadium or aluminum, and
the one or more shared atoms comprise at least one of oxygen, nitrogen, or carbon, and
the first composition and the second composition are related as shown bythe formula
L,M1,M2,Zn,Ag,Ga,In,Ln,Y,Sc)ₗ(Zr,V,Ta,Nb,Hf,Ti,Al,Cr,Ln)ₘ(P,Si,B,V,Al)ₙ(O,C,N)_{w}
wherein L=alkali, M1=alkaline earth, M2=transition metal, Ln=rare earth; l, m, n are so chosen that a charge balance is maintained; and w=12 or 24;
wherein the apparatus is exposed to a corrosive operating environment at a temperature range of 25-1500° C. selected from one of: an environment comprising halogen, a plasma etching environment, a reactive ion etching environment, a plasma cleaning environment, and a gas cleaning environment.

2. The processing apparatus as defined in claim 1, wherein the second composition in the coating layer comprises boron.

3. The processing apparatus as defined in claim 1, wherein the second composition in the coating layer aluminum.

4. The processing apparatus as defined in claim 1, wherein the one or more shared atoms in the coating layer comprise nitrogen.

5. The processing apparatus as defined in claim 1, wherein the one or more shared atoms in the coating layer comprise carbon.

6. The processing apparatus as defined in claim 1, wherein the first composition in the coating layer comprises phosphorus and the one or more shared atoms comprise nitrogen.

7. The processing apparatus as defined in claim 1, wherein the second composition in the coating layer comprises silicon and the one or more shared atoms comprise nitrogen.

8. The processing apparatus as defined in claim 1, wherein the second composition in the coating layer comprises boron and the one or more shared atoms comprise nitrogen.

9. The processing apparatus as defined in claim 1, wherein the second composition in the coating layer comprises aluminum and the one or more shared atoms comprise nitrogen.

10. The processing apparatus as defined in claim 1, wherein the second composition in the coating layer comprises phosphorus and the one or more shared atoms comprise carbon.

11. The processing apparatus as defined in claim 1, wherein the second composition in the coating layer comprises silicon and the one or more shared atoms comprise carbon.

12. The processing apparatus as defined in claim 1, wherein the second composition in the coating layer comprises boron and the one or more shared atoms comprise carbon.

13. The processing apparatus as defined in claim 1, wherein the second composition in the coating layer comprises aluminum and the one or more shared atoms comprise carbon.

14. The processing apparatus as defined in claim 1, wherein the second composition in the coating layer comprises boron and the one or more shared atoms comprise oxygen.

15. The processing apparatus as defined in claim 1, wherein the second composition in the coating layer comprises aluminum and the one or more shared atoms comprise oxygen.

16. The processing apparatus as defined in claim 1, wherein the second composition in the coating layer comprises two or more of P, Si, Al, V or B.

17. The processing apparatus as defined in claim 1, wherein the ratio of the first composition to the second composition in the coating layer is 1:1.5.

18. The processing apparatus as defined in claim 1, wherein the metal cation in the coating layer is a metal of Group I of the periodic table of elements, is a metal of Group II of the periodic table of elements, is a metal of the Lanthanide series, or is a transition metal.

19. The processing apparatus as defined in claim 18, wherein the metal cation in the coating layer comprises three or more of Li, Na, K, Rb, Cs, Mg, Ca, Sr, Ba, Ga, In, Ag, Zn, Cr, Mn, Fe, Co, La, Lu, or a metal of the Lanthanide series.

20. The processing apparatus as defined in claim 1, wherein the first composition in the coating layer comprises zirconium.

21. The processing apparatus as defined in claim 1, wherein the metal cation in the coating layer is present in an amount, or absent, sufficient that the interstitial sites are one or more of:
empty,
fully occupied, or
partially occupied.

22. The processing apparatus as defined in claim 1, wherein the metal cation in the coating layer is present in an amount sufficient that the interstitial sites are off a stoichiometric balance.

23. The processing apparatus as defined in claim 1, wherein the coating layer further comprising a plurality of particles dispersed therein.

24. The processing apparatus as defined in claim 23, wherein the particles in the coating layer comprise aluminum nitride, silicon carbide, or both aluminum nitride and silicon carbide.

25. The processing apparatus as defined in claim 21, wherein the particles in the coating layer have an average particle size that less than about 50 micrometers.

26. The processing apparatus as defined in claim 1, wherein the coating layer has the property of a coefficient of thermal expansion in a range of from about 2.2 to about 2.4.

27. The processing apparatus as defined in claim 1, wherein the coating layer has an etch rate of less than 100 Angstroms per min when exposed to the corrosive operating environment at a temperature in a range of greater than about 100 degrees Celsius.

28. The processing apparatus as defined in claim 27, wherein the coating layer has an etch rate of less than 50 Angstroms per min when exposed to the corrosive operating environment at a temperature in a range of greater than about 100 degrees Celsius.

29. The processing apparatus as defined in claim 28, wherein the coating layer has an etch rate of less than 50 Angstroms per min when exposed to the corrosive operating environment at a temperature in a range of greater than about 400 degrees Celsius.

30. The processing apparatus as defined in claim 29, wherein the coating layer has an etch rate of less than 50 Angstroms per min when when exposed to the corrosive operating environment at a temperature in a range of greater than about 650 degrees Celsius.

31. The processing apparatus as defined in claim 1, wherein the coating layer when exposed to 18 weight percent feedstock gas at about 400 degrees Celsius comprising oxygen gas and at least one of carbon tetrachloride gas or nitrogen fluoride gas has an etch rate of less than about 10 Angstroms per minute.

32. The processing apparatus as defined in claim 1, wherein the NZP-type coating layer is of the formula (Ca_{0.5-x}, Mgₓ)Zr₂(PO₄)₃ where x ranges between 0.05 and 0.45.

33. The processing apparatus as defined in claim 1, wherein the NZP-type coating layer is of the formula RZr₄P₆O₂₄ wherein R is one or more cations of group IIa in the periodic table.

34. The processing apparatus as defined in claim 1, wherein the NZP-type coating layer is of the formula R_{1-Y}⁴⁺ R_{Y}¹⁺ R_{Y}³⁺ V_{2-X} P_{X} O₇, wherein X is from about 0.1 to about 1.9, Y is from about 0.0 to about 0.4, and wherein R⁴⁺ selected from the group consisting of Hf, Zr, Zrₐ M_{b}, Hfₐ M_{b} and mixtures thereof, wherein a+b=1, M is selected from the group consisting of Ti, Ce, Th, U, Mo, Pt, Pb, Sn, Ge and Si, R¹⁺ is selected from alkali earth metals, and R³⁺ is selected from the group of rare earth metals.

35. The processing apparatus as defined in claim 1, wherein the NZP-type coating layer is of the formula R_{1+X}M₄P_{6-2X}Si_{2X}O₂₄ wherein X is between 0.2 and 0.8, R is one or more cations of group IIa in the periodic table, and M is selected from the group consisting of Hf, Zr, Zrₐ M_{b}, Hfₐ M_{b} and mixtures thereof.

36. The processing apparatus as defined in claim 1, wherein the NZP-type coating layer is of the formula A_{2-X}³⁺ A_{y}⁴⁺ M_{z}³⁺ M_{3-y}⁶⁺ P_{y}O₁₂ where A³⁺ is a metal having an oxidation state of +3, A⁴⁺ is a metal having an oxidation state of +4, M³⁺ is a metal having an oxidation state of +3, M⁶⁺ is a metal having an oxidation state of +6, 0<=y<=2, 0.1<=x<=1.9; and x=y+z.

37. The processing apparatus as defined in claim 1, wherein the NZP-type coating layer is of the formula Rₓ Z₄ P_{6-y} Si_{y} O₂₄, wherein 0<=x<=8, 0<=y <=6, R is selected from the group consisting of Li, Na, K, Rb, Cs, Mg, Ca, Sr, Ba, Y, lanthanides, and combinations thereof; Z is selected from the group consisting of Zr, Ti, Nb, Ta, Y, lanthanides, and combinations thereof.

38. The processing apparatus as defined in claim 1, wherein the NZP-type coating layer has a crystalline structure indicated by the formula:
(L,M1,M2,Zn,Ag,Ga,In,Ln,Y,Sc)ₗ(Zr,V,Ta,Nb,Hf,Ti,Al,Cr,Ln)ₘ(P,Si,V,B,Al)ₙ(O,C,N)_{w}
wherein L=alkali, M1=alkaline earth, M2=transition metal, Ln=rare earth; w=12 or 24; and l, m, n are so chosen for a charge balance maintained at a valence equivalent to that of the total non metals O,C,N.

39. The processing apparatus as defined in claim 1, wherein the NZP-type coating layer has a CTE that is within about 10 percent of the substrate CTE.

40. The processing apparatus as defined in claim 1, wherein the base substrate comprises an electrically conducting material selected from the group of graphite, refractory metals, transition metals, rare earth metals and alloys thereof.

41. The processing apparatus as defined in claim 1, wherein the base substrate comprises an electrically insulating material selected from the group of oxides, nitrides, carbides, carbonitrides or oxynitrides of elements selected from a group consisting of B, Al, Si, Ga, Y; a high thermal stability zirconium phosphate having an NZP structure of NaZr₂(PO₄)₃; refractory hard metals; transition metals; oxide, oxynitride of aluminum, and combinations thereof.

42. A processing apparatus for use in a corrosive operating environment at a temperature range of 25-1500° C., the apparatus comprising:
a base substrate having a coefficient of thermal expansion (CTE), the base substrate comprising at least one of a nitride, carbide, carbonitride or oxynitride of elements selected from a group consisting of B, Al, Si, Ga, refractory hard metals, transition metals, and combinations thereof;
at least one electrode disposed on the base substrate, the electrode has a coefficient of thermal expansion (CTE) in a range of 0.75 to 1.25 times that of the base substrate CTE;
an NZP-type coating layer disposed on a surface of the base substrate, the coating layer comprising:
a first composition and a second composition, wherein the first composition and the second composition are capable of forming a crystalline structure with three-dimensional network of octahedra and tetrahedra linked by one or more shared atoms, wherein
the first composition comprises one or more of Zr, V, Ta, Nb, Hf, Ti, Al, Cr, or a metal of the Lanthanide series,
the second composition comprises at least one of phosphorus, silicon, boron, vanadium or aluminum, and
the one or more shared atoms comprise at least one of oxygen, nitrogen, or carbon, and
the first composition and the second composition are related as shown by the formula
L,M1,M2,Zn,Ag,Ga,In,Ln,Y,Sc)ₗ(Zr,V,Ta,Nb,Hf,Ti,Al,Cr,Ln)ₘ(P,Si,B,V,Al)ₙ(O,C,N)_{w}
wherein L=alkali, M1=alkaline earth, M2=transition metal, Ln=rare earth; w=12 or 24; and the values of l, m, n are so chosen that the charge balance is maintained; and
a metal cation, wherein the metal cation is disposed within an interstitial site defined by the crystalline structure;
wherein the operating environment is one of an environment comprising halogen, a plasma etching environment, a reactive ion etching environment, a plasma cleaning environment, and a gas cleaning environment.

43. The processing apparatus of claim 42, wherein the NZP-type coating layer has an electrical resistivity in a range of from about 1×10¹⁵ to about 1×10¹⁸, and an dielectric constant of greater than about 7.

44. The processing apparatus of claim 42, further comprising a second coating layer disposed on the NZP-type coating layer, the second coating layer comprising at least one of an oxide, nitride, oxynitride, carbide, or nitride of one or more elements selected from a group consisting of Al, B, Si, Ga, refractory hard metals, transition metals, and combinations thereof.

45. The processing apparatus of claim 42, further comprising a second coating layer disposed under the NZP-type coating layer, the second coating layer comprising at least one of an oxide, nitride, oxynitride, carbide, or nitride of one or more elements selected from a group consisting of Al, B, Si, Ga, refractory hard metals, transition metals, and combinations thereof.

46. The processing apparatus of claim 42, wherein the NZP-type coating layer has a porosity of less than about 5 volume percent.

47. The processing apparatus of claim 42, wherein the NZP-type coating layer has a thermal diffusivity greater than about 6×10⁻⁷ m²/sec.

48. The processing apparatus of claim 42, wherein the NZP-type coating layer CTE is about 2.3.

49. A method for producing a wafer processing apparatus, comprising the steps of:
providing a base substrate comprising at least one of a nitride, carbide, carbonitride or oxynitride of elements selected from a group consisting of B, Al, Si, Ga, refractory hard metals, transition metals, and combinations thereof;
depositing a film electrode onto the base substrate, the film electrode has a CTE ranging from 0.75 to 1.25 of the base substrate layer;
coating the base substrate and the film electrode with a coating layer having a CTE ranging from 0.75 to 1.25 of the film electrode,
wherein the coating layer has the formula
(L,M1,M2,Zn,Ag,Ga,In,Ln,Y,Sc)ₗ(Zr,V,Ta,Nb,Hf,Ti,Al,Cr,Ln)ₘ(P,Si,B,V,Al)ₙ(O,C,N)_{w}
wherein L=alkali, M1=alkaline earth, M2=transition metal, Ln=rare earth; w=12 or 24; and the values of l, m, n are so chosen that the charge balance is maintained.
